(19) United States
(12) Patent Application Publication
(10) Pub. No.: US 2004/0231599 A1
(43) Pub. Date: Nov. 25, 2004

(54) Process chamber with a base with sectionally different rotational drive and layer deposition method in such a process chamber

(76) Inventors: Markus Schwambera, Aachen (DE); Walter Franken, Eschweiler (DE); Gerhard Karl Strauch, Aachen (DE)

Correspondence Address: ST. ONGE STEWARD JOHNSTON & REENS, LLC, 986 BEDFORD STREET, STAMFORD, CT, 06905-5619, US

(21) Appl. No.: 10/754,817

(22) Filed: Jan. 9, 2004

Related U.S. Application Data
(63) Continuation of application No. PCT/EP02/06294, filed on Jun. 10, 2002.

(30) Foreign Application Priority Data
Jul. 12, 2001 (DE) 101 33 914.3

(51) Int. Cl. C23C 16/00

(52) U.S. Cl. 118/728; 427/248.1

(57) ABSTRACT

The invention relates to a method for the deposition of, in particular crystalline layers on a substrate lying on rotating substrate holders in a process chamber. The substrate holders are arranged around the center of a rotating substrate holder support. Said substrate holder support forms a process chamber base together with the substrate holders, which is opposite a process chamber cover which a central gas inlet device, through which, together with a carrier gas, one or several gaseous starting materials may be introduced into a decomposition zone, arranged above a heated central region of the process chamber floor, surrounded by a diffusion zone, from which the decomposition zone, from which the decomposition products are transported radially outwards in the carrier gas stream to the substrate. According to the invention, the supply of decomposition products to the substrate may be equilibrated, whereby the central region of the process chamber base is rotated relative to the substrate holder support and to the process chamber cover or the gas inlet device.

This application is a continuation of pending International Patent Application No. PCT/EP02/06294 filed Jun. 10, 2002 which designates the United States and claims priority of pending German Application No. 101 33 914.3 filed Jul. 12, 2001.

### FIELD OF THE INVENTION

The invention relates to a method for depositing in particular crystalline layers on substrates lying on rotationally driven substrate holders in a process chamber, the substrate holders being disposed around the center of a rotationally driven substrate holder carrier, which substrate holders together with the substrate holder carrier form a process chamber base, opposite which there is a process chamber cover with a central gas inlet element, through which one or more gaseous starting materials are introduced together with a carrier gas into a decomposition zone which is disposed above a heated central region of the process chamber base and is surrounded by a diffusion zone, from which the decomposition products transported in the radially outwardly flowing carrier stream reach the substrate.

The invention also relates to an apparatus for depositing in particular crystalline layers on in particular crystalline substrates resting on rotationally drivable substrate holders in a process chamber of the apparatus, the substrate holders being disposed around the rotational center of a rotationally drivable substrate holder carrier, which substrate holders together with the substrate holder carrier form a process chamber base, opposite which there is a process chamber cover with a central gas inlet element, the central region of the process chamber base giving off heat to one or more gaseous starting materials introduced into the process chamber through the gas inlet element as a result of heating.

Such an apparatus and such a method belong to the prior art. Used in particular as substrates are semiconductor wafers. They may be III-V semiconductor wafers. These disks, also referred to as “wafers”, are placed onto the substrate holders. The substrate holders are rotationally driven, as described in U.S. Pat. No. 4,860,687. There, the substrate holders have a circular disk shape and rotate. They rotate for example on a gas cushion, which is maintained by gas streams introduced into the substrate holder carrier, where they flow through channels. It is ensured by a special outlet nozzle, in particular in the form of a spiral-arc-like groove, that the gas stream forms not only a carrying gas cushion but also a rotationally driving gas cushion for the substrate holder disks. As an alternative to this, mechanical rotary drives are also known in the prior art. The substrate holder disks are arranged in a planetary manner around the center of the substrate holder carrier. The substrate holder carrier is itself rotationally driven. This is described for example by DE 19043600. Over the center of the substrate holder carrier there is a gas inlet element, associated with the cover of the process chamber. The gas inlet element has a number of gas outlet zones. Flowing through a central gas outlet zone is the hydride, for example arsine or phosphine. Flowing into the process chamber through gas outlet zones peripheral to this central zone are the organometallic components, for example trimethylgallium or trimethylindium. The process chamber base is heated from below, for example by means of a high-frequency heater. The process chamber cover can likewise be heated or cooled according to requirements. The central region of the process chamber base disposed directly beneath the gas inlet element gives off heat to the process gas flowing into the process chamber from the gas inlet element, by means of radiation but in particular by means of heat conduction. The gaseous starting materials transported within the process gas by means of the carrier gas stream are decomposed pyrolytically as a result of decomposition of this heating. In the ideal case, the heating is to take place completely uniformly in the circumferential direction, in order that the substrates disposed in a planetary manner around the center of the substrate holder carrier are evenly supplied with decomposition products, which diffuse from the diffusion zone extending around the central region and build up a layer there. In reality, an exact rotationally symmetrical decomposition zone cannot be achieved, since homogeneous temperature distribution cannot be achieved in the central region owing to material inhomogeneities or tolerances in the production dimensions.

It is therefore an object of the invention to provide measures by means of which the supply of the substrates with decomposition products is made more uniform.

The object is achieved in the first instance and substantially by the solutions specified in claims 1 and 2, it being provided that the central region of the process chamber base is rotationally drivable or rotationally driven in relation to the substrate holder carrier and the process chamber cover or the gas inlet element. The subjects specified in the further claims relate to both advantageous developments of the subject-matter of the method specified in claim 1 or the apparatus specified in claim 2 and at the same time to independent technical solution proposals that are independent of said developments and of the aforementioned object. It is proposed there in particular that the substrate holders and a center plate, which with its surface forms the central region, are rotationally mounted on a gas cushion or mechanically. As the center plate lies on a gas cushion, the heat supply to the center plate can be set by means of the thermal conductivity of the gas. It is therefore provided that gas forming the gas cushion can consist of various components. One component may be a gas with a high thermal conductivity. The other component may be a gas with a low thermal conductivity. Suitable mixing of the two gases allows the heat transport, and consequently the surface temperature, to be set. The center plate may, however, also be rotationally driven by a gear mechanism or in some other way. As a consequence of the rotation of the center plate, inhomogeneities of the surface temperature of the center plate that exist in the circumferential direction are averaged out. The center plate may consist of graphite. It may be coated. It may consist of an inert metal, for example of molybdenum, of ceramic or of quartz. The center plate may rotate in the same direction as the substrate holder carrier. It then runs altogether at a higher rotational speed in relation to the gas inlet element or the process chamber cover. The center plate may, however, also rotate in the opposite direction. It should be ensured, however, that the rotational speed deviates from the rotational speed of the substrate holder carrier, in order that the required relative movement with respect to the gas inlet element or the process chamber cover is ensured. In a preferred configuration of the invention, it is provided that the center plate is carried by the substrate holder carrier. This has the advantage that the center plate can rotate in relation to the process chamber cover or the gas inlet element faster than the substrate holder carrier. In a preferred configuration of the invention, the substrate holder carrier comprises an outer ring part, which receives the substrate holders. This outer ring part is clamped by means of two clamping plates disposed in the center of the ring part. These clamping plates may be screwed to gas supply pipes, which are disposed coaxially in relation to one another. The center plate may be arranged in the free space in the center of the ring. The center plate then lies in a pot-shaped recess, the walls of which are formed by the inner ring walls of the ring body. The base of this pot-shaped recess is formed by the upper clamping plate. The way in which the clamping plates are disposed with respect to the annular body is described for example by DE 19043600.

### BRIEF DESCRIPTION OF DRAWINGS

Exemplary embodiments of the invention are explained below on the basis of accompanying drawings, in which:

FIG. 1 shows a diagonal section through the center of a process chamber of an apparatus according to the invention (section according to the line I-I of FIG. 2),

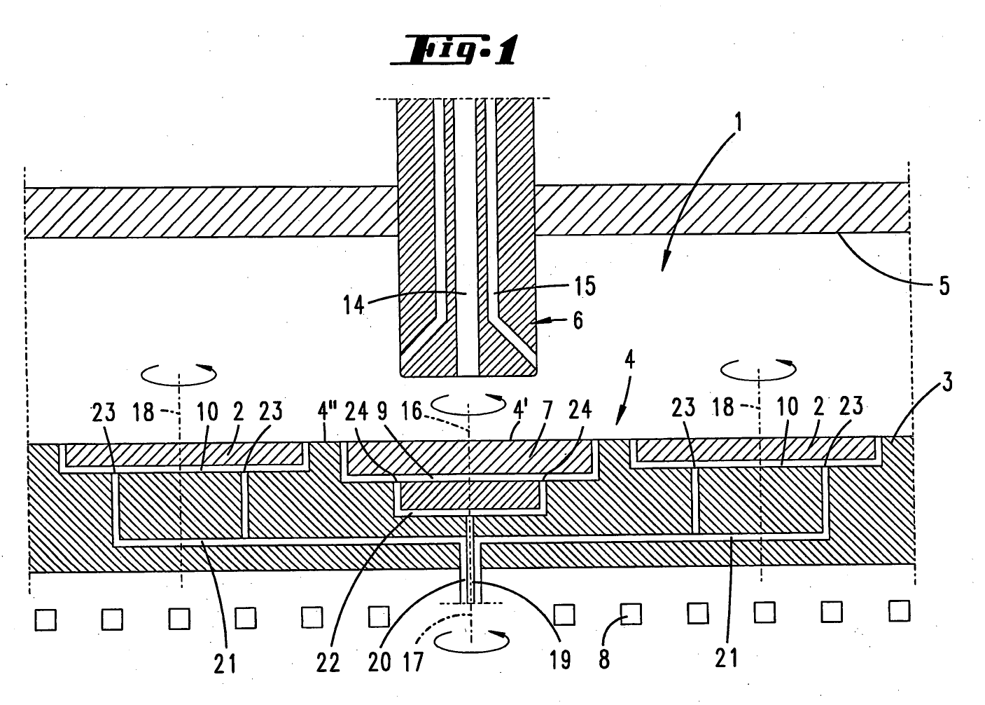

FIG. 2 shows the plan view of the process chamber base of the apparatus according to FIG. 1 and

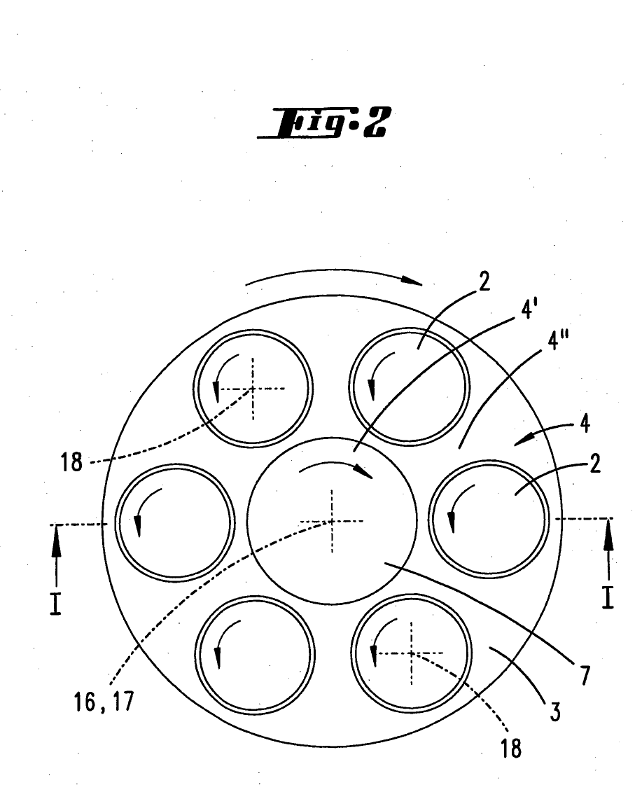

FIG. 3 shows a representation according to FIG. 1 in a section which corresponds to the line I-I in FIG. 2.

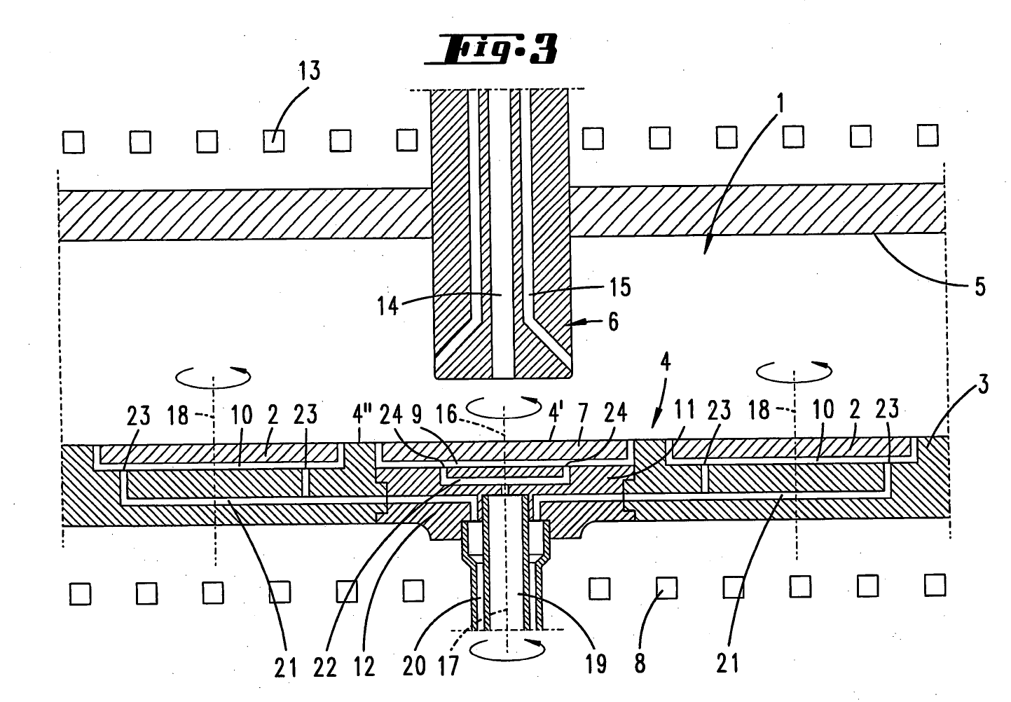

### DETAILED DESCRIPTION OF DRAWINGS

The process chamber 1 has a cylindrical-symmetrical shape. It has a base 4 and a cover 5. The cover 5 may comprise a graphite plate. In its center, the circular-disk-shaped graphite plate 5 has an opening. Through this opening, a gas inlet element 6 protrudes from the outside into the process chamber 1. The gas inlet element 6 has a central supply line 14, through which AsH₃ or PH₃ is supplied. The supply takes place together with a carrier gas, for example H₂ or N₂. Extending peripherally around the hydride supply line 14 is the MO supply line 15, through which the organometallic components, for example TMI or TMG, are introduced into the process chamber, likewise with a carrier gas.

The process chamber base 4 mentioned is formed substantially by a substrate holder carrier 3, which is a rotationally driven plate which may consist of the same material as the process chamber cover 5. The process chamber base 4 may consist of graphite, metal, quartz or ceramic.

The substrate holder carrier 3 has a number of pot-shaped recesses disposed in circumferentially equal distribution at the same radial distance from the center. Channels 21 open into these pot-shaped recesses in the form of nozzles 23. The configuration of the nozzles is described by U.S. Pat. No. 4,860,687. Reference is made to this document in this respect. The nozzles 23 are configured in such a way that the circular-disk-shaped substrate holders 2 lying in the pot-shaped recesses are rotationally driven by the gas stream emerging from the nozzles 23. The substrate holders 2 lie on a gas cushion. The substrate holders 2 are located in a peripheral zone 4″ of the base 4. This zone corresponds to the diffusion zone in the gas phase lying there above. From this zone, the decomposition products produced in a decomposition zone lying in the center region are to be transported, in order to reach the substrate.

The central region 4′ of the process chamber base 4 is formed by a rotationally driven center plate 7. In a way similar to the substrate holders 2, this center plate has the form of a circular disk. However, in the exemplary embodiment, its diameter is greater than the diameter of the substrate holders 2. The diameter of the center plate 7 may, however, also be differently dimensioned. It may, for example, be less than the diameter of the substrate holders 2. The center plate 7 also lies on a gas cushion. This gas cushion is maintained by a gas which emerges from the nozzles 24 through a gas supply line 19 and through channels 22. With regard to the configuration of the nozzles, reference is also made here to U.S. Pat. No. 4,860,687. The nozzles 24 are also capable not only of forming the gas cushion on which the center plate 7 lays. The nozzles also provide a rotary drive for the center plate 7. The center plate 7 preferably rotates in the same direction as the substrate holder carrier 3, which is driven by means of pipes forming the gas supply line 19 and 20. The axis of rotation 16 of the center plate 7 and the axis of rotation 17 of the substrate holder carrier 3 optimally coincide. The rotational movement of the center plate 7 may also take place in a mechanical way, for example by means of a drive motor and transmission shafts or wheels.

The way in which the pipes of the gas supply lines 19, 20 are coaxially disposed has the effect that gas required for the gas cushion and the rotary drive of the center plate 7 flows in the central pipe 19.

The substrate holder carrier 3 is heated from below by means of a high-frequency heater 8. It is also possible, however, to heat the substrate holder by means of infrared light or by means of an electrical resistance. The center plate 7 is heated substantially by heat conduction and heat radiation. The heat transport through the gas gap 9 can be influenced by changing the thermal conductivity of the gas. In this way, the surface temperature in the central region 4′ can also be influenced. By variation of the thermal conductivity, it is possible for example to pass a mixture of hydrogen and nitrogen through the pipeline 19 in various mixing ratios.

The heat transfer from the substrate holder carrier to the substrate holder 2 can also be set by means of the nature of the gas forming the gas cushion 10. The center plate 7 may consist of graphite, of an inert metal, for example molybdenum, ceramic or of quartz. As a result of the rotationally driven central region 4′, inhomogeneities extending in the circumferential direction are averaged out. As a result of a viscous coupling of the gas above the center plate 7, the gas is entrained by the rotation there. This leads to an increase in the homogeneity and in this way to minor deviations in the qualities of the layers of the individual substrates.

All disclosed features are (in themselves) pertinent to the invention. The disclosure content of the associated/attached priority documents (copy of the prior patent application) are also hereby incorporated in full in the disclosure of the application, including for the purpose of incorporating features of these documents in claims of the present application.

1. Method for depositing crystalline layers on substrates lying on rotationally driven substrate holders in a process chamber, the substrate holders being disposed around the center of a rotationally driven substrate holder carrier, which substrate holders together with the substrate holder carrier form a process chamber base, opposite which there is a process chamber cover with a central gas inlet element, through which one or more gaseous starting materials are introduced together with a carrier gas into a decomposition zone which is disposed above a heated central region of the process chamber base and is surrounded by a diffusion zone, from which the decomposition products transported in the radially outwardly flowing carrier gas stream reach the substrate, characterized in that the central region of the process chamber base is rotationally driven in relation to the substrate holder carrier and the process chamber cover or the gas inlet element.

2. Apparatus for depositing crystalline layers on crystalline substrates resting on rotationally drivable substrate holders in a process chamber of the apparatus, the substrate holders being disposed around the rotational center of a rotationally drivable substrate holder carrier, which substrate holders together with the substrate holder carrier form a process chamber base, opposite which there is a process chamber cover with a central gas inlet element, the central region of the process chamber base giving off heat to one or more gaseous starting materials introduced into the process chamber through the gas inlet element as a result of heating, characterized in that the central region of the process chamber base is rotationally drivable in relation to the substrate holder carrier and the process chamber cover or the gas inlet element.

3. Method according to claim 1, characterized in that the substrate holders and a center plate, which with its surface forms the central region, are rotationally mounted on a gas cushion.

4. Method according to claim 3, characterized in that a thermal conductivity of the gas cushion carrying and rotationally driving the center plate can be set by choosing the gas mixture, the gas mixture comprising a gas with a high thermal conductivity and a gas with a low thermal conductivity.

5. Method according to claim 3, characterized in that the center plate consists of graphite, in particular coated graphite, an inert metal, ceramic or quartz.

6. Method according to claim 3, characterized in that the center plate rotates in the same direction as or in the opposite direction to the substrate holder carrier.

7. Method according to claim 3, characterized in that the center plate is carried by substrate holder carrier.

8. Method according to claim 3, characterized in that the substrate holder carrier comprises more than one part and is held centrally by two clamping plates, the center plate lying above the an uppermost of the two clamping plates.

9. Method according to claim 3, characterized by a coaxial supply line of the gas streams forming the gas cushions.

10. Method according to claim 3, characterized in that the center plate is rotationally driven mechanically, by means of a drive shaft or by means of drive wheels.

11. Apparatus according to claim 2, characterized in that the substrate holders and a center plate, which with its surface forms the central region, are rotationally mounted on a gas cushion.

12. Apparatus according to claim 11, characterized in that a thermal conductivity of the gas cushion carrying and rotationally driving the center plate can be set by choosing the gas mixture, the gas mixture comprising a gas with a high thermal conductivity and a gas with a low thermal conductivity.

13. Apparatus according to claim 11, characterized in that the center plate consists of graphite, an inert metal, ceramic or quartz.

14. Apparatus according to claim 11, characterized in that the center plate rotates in the same direction as or in the opposite direction to the substrate holder carrier.

15. Apparatus according to claim 11, characterized in that the center plate is carried by substrate holder carrier.

16. Apparatus according to claim 11, characterized in that the substrate holder carrier comprises more than one part and is held centrally by two clamping plates, the center plate lying above an uppermost of the two clamping plates.

17. Apparatus according to claim 11, characterized by a coaxial supply line of the gas streams forming the gas cushions.

18. Apparatus according to claim 11, characterized in that the center plate is rotationally driven mechanically by means of a drive shaft or by means of drive wheels.
